(19) United States
(12) Patent Application Publication
(10) Pub. No.: US 2007/0108630 A1
(43) Pub. Date: May 17, 2007

(54) ARTICLE HAVING ISLAND STRUCTURE AND PRODUCING METHOD THEREOF

(76) Inventors: Keita MORI, Tokyo (JP); Fumitoshi Kobayashi, Tokyo (JP)

Correspondence Address: WHITHAM, CURTIS & CHRISTOFFERSON & COOK, P.C., 11491 SUNSET HILLS ROAD, SUITE 340, RESTON, VA, 20190, US

(21) Appl. No.: 11/553,058

(22) Filed: Oct. 26, 2006

(30) Foreign Application Priority Data
Nov. 14, 2005 (JP) P2005-328290

(51) Int. Cl. H01L 23/48

(52) U.S. Cl. 257/783

(57) ABSTRACT

A producing method according to the invention of an article having an island structure fundamentally includes a step of coating a forming material having the fluidity on a substrate, a step of facing the substrate and a forming mold with the forming material having the fluidity interposed therebetween to pressurize, a step of applying energy such as heat or light in a pressurized state to cure the forming material in the forming mold, and a step of releasing the forming mold. A producing method of a formed article where a non-forming portion is not remained and only a forming portion is remained is provided. After the step of forming, before the step of curing, a step of removing a forming material having the fluidity outside of the forming mold to clean is inserted. A cleaning solution that dissolves a forming material before curing can remove the forming material.

### BACKGROUND OF THE INVENTION

1. Field of the Invention

The invention relates to an article having an island structure in which an island body is partially formed on a surface of a substrate, which is mainly used in an optical field such as light communication, light measurement and optical recording, and a producing method thereof.

2. Related Art

A forming technology is widely used as a method of producing articles having an identical shape in large quantities. Pressure forming that is one of the forming technologies is a method where a forming mold is pressed against a deformable work deployed on a substrate, that is, a forming material, to apply pressure to transfer a surface shape of the forming mold on the forming material.

As the forming materials deformable at low temperatures, resin materials are typical. For instance, photocurable materials that have the fluidity at room temperature and can be cured upon irradiation of UV rays are frequently used.

Furthermore, sol-gel materials that are organic/inorganic composite materials are known as well. A method of producing articles having fine irregular shape on a surface with a sol-gel material is disclosed in, for instance, JP-A 11-314927.

The sol-gel materials are materials obtained by adding alcohol, water and a catalyst to compounds such as alkylalkoxysilanes to hydrolyze. In general, these are used after heating and partially removing volatilizing components. Raw material compounds can be selected from a variety of kinds of compounds and these can be used in combinations in some cases.

In the case of a compound containing silicon such as an alkoxysilane material being used as a raw material, when, after the forming, heating is applied to partially remove organic components, a formed body becomes a state close to an inorganic material mainly made of silicon oxide. Accordingly, formed articles superior in the heat resistance and weather resistance to resin materials can be provided.

A forming method is carried out in such a manner that, as shown in FIGS. 8A through 8D, on a surface of a substrate 110, a forming material 120 having the fluidity is coated (coating step, FIG. 8A), thereon a forming mold 130 is pressed to pressurize (forming step, FIG. 8B), followed under a pressurized state by heating or irradiating UV rays to cure the forming material (curing step, FIG. 8C), and further followed by releasing from the mold (mold releasing step, FIG. 8D). Thereby, a formed article 150 on which a shape of the forming mold is transferred can be obtained. By contrast, a forming material may be coated on the forming mold so as to fill the forming material and a substrate may be pressed against this.

According to such a forming technology, a fine irregular shape can be formed on a surface. Accordingly, the technology is suitable as a producing method of various kinds of optical elements necessary in the optical field such as a microlens array and a diffraction grating (for instance, JP-A 2001-9843). Since such optical elements each are small in size in many cases, it is inefficient to produce these one by one according to the forming method. When an element is small in size, without using so large a substrate, many elements can be simultaneously formed on one substrate and by cutting these individual elements can be obtained. That is, in such a case, it is advantageous to produce by one-time forming operation a structure where a plurality of portions having a desired shape is arranged on the substrate.

Furthermore, in an array element where a plurality of light-emitting elements or light receiving elements is arranged on a substrate or a so-called optical integrated circuit or opto-electronic integrated circuit where semiconductor elements such as electronic elements, light-emitting elements and light receiving elements are integrated, when, in addition to the elements, lens elements as well are integrated, a structure where a plurality of portions having a desired shape is arranged in predetermined positions can be formed by one-time forming.

In such a case, as shown in FIGS. 9A through 9D, on a surface of a substrate 210 or on a surface of a substrate on which a semiconductor element and so on have been formed, a forming material 120 having the fluidity is coated (coating step, FIG. 9A) and thereon a plurality of forming molds are pressed to pressurize (forming step, FIG. 9B). A plurality of forming molds may be individually independent. However, as shown in the drawing, a plurality of forming molds may be disposed on a support 235 to form one forming mold 230 having a plurality of forming portions 233. Under a pressurized state, heating or UV irradiation is applied to cure the forming material (curing step, FIG. 9C) followed by releasing (mold releasing step, FIG. 9D) and thereby a formed article 250 thereon a shape of the forming mold is transferred can be obtained.

However, existing technologies have problems such as shown below.

A first problem is in that in the case of a structure such as mentioned above being formed, a forming mold used is smaller than a substrate on which a shape of the forming mold is transferred. Accordingly, when a forming material is coated on the substrate, a portion outside of the forming mold is not pressed and remains on the substrate. Furthermore, even when a forming material is filled and coated in the forming mold, the forming material likely to run over in the periphery of the forming mold.

As shown in FIG. 10, when the pressed forming material runs outside of the forming mold, after curing, a non-forming portion 124 of a forming material 122 is formed in a swelling state. Furthermore, a formed portion 126 on which a surface shape of the forming mold is transferred is formed in recess. Accordingly, outside of the formed portion 126 prepared, a non-forming portion 124 remains, and, when the formed portion is used, in some cases, a function thereof is disturbed. Furthermore, there is a case where a once formed body is used as a forming mold (replica) that is used in an actual production, in such a case, the external non-forming portion 124 disturbs to make difficult to use as a forming mold.

As a second problem, when a thin film is necessarily formed on a surface of a formed body shown in FIG. 10 by means of a vacuum deposition method, a film on a surface of the non-forming portion is likely to peel. It is assumed due to that since the non-forming portion 124 is not pressurized, the thermal expansion coefficient thereof is large, and thereby, at the layering, a stress is applied on the thin film.

From the problems mentioned above, it is preferred that, after the forming, the non-forming portion on the substrate is removed and a structure where only a formed portion is remained in island is formed. However, in order to remove the non-forming portion without causing damage on the formed portion, a complicated step is necessary. When such a step is added, an advantage of the forming process that is simple and adequate to the mass production is damaged.

### SUMMARY OF THE INVENTION

The invention was carried out in view of the problems of the existing technologies and intends to provide an article having an island structure, in which in the forming step the non-forming portion is not remained and only a formed portion is remained. Furthermore, the other object of the invention is to provide a producing method of an article having an island structure.

An article according to the invention and having an island structure is one in which, on a surface of a substrate or a surface of a solid material layer formed on a surface of a substrate, a plurality of island bodies is arranged and formed separated from each other island-like, the island body containing a substance obtained by hydrolyzing and curing a sol-gel material, and, in a surrounding portion of a portion where an island body is formed, a surface of a substrate or a surface of a solid material layer being exposed.

In such a structure, since only an island body portion is formed protruded on a substrate, when the portion is used, a function thereof is not disturbed. Furthermore, when this is used as a forming mold as well, there is no inconvenience.

In the above configuration, it is preferable that with glass or semiconductor as a substrate and with a semiconductor layer as a solid material layer, a surface of substrate and/or a surface of solid material layer is partially provided with a conductive film to form a plurality of light-emitting elements and/or light receiving elements on a semiconductor layer, on a surface of the semiconductor layer a conductive film is formed processed as an electrode, and an island body is formed at least partially on a light-emitting element and/or a light receiving element.

According to such a configuration, an optical component where a semiconductor light-emitting element or light receiving element and an optical element such as a lens are integrated can be provided. Since a light-emitting element can be formed only on a predetermined place on the substrate, it can be avoided to adversely affecting on a whole of optical components.

All island bodies can be formed into substantially same shape. Furthermore, on a surface of the island body, a predetermined irregular structure can be formed. Still furthermore, a linearly or two-dimensional arrangement according to a rule can be adopted.

A producing method according to the invention of an article having an island structure includes a step of coating a forming material having the fluidity on a substrate or filling/coating the same in a forming mold, a step of facing the substrate and a forming mold with the forming material having the fluidity interposed therebetween to pressurize, a step of removing the forming material having the fluidity outside of the forming mold to clean, a step of applying energy such as heat or light under a pressurized state to cure the forming material in the forming mold and a step of releasing the forming mold.

According to the above steps, in the forming step, a non-forming portion outside of the forming mold can be removed before curing, and, thereby, only a curing portion can be remained. Furthermore, when the step of cleaning is added, without damaging the substrate, an island structure can be prepared on a surface of the substrate. Still furthermore, when a structure is in advance formed on a surface of the substrate as well, the portion, without covering with a sol-gel film, can be exposed; accordingly, a function of the structure on the surface of the substrate is neither damaged. Furthermore, since a sol-gel material that covers a periphery of the mold can be removed as well, the mold releasing can be readily applied.

The cleaning step preferably includes a method of dipping a part or a whole of a substrate covered with the forming mold in a cleaning solution that dissolves the forming material having the fluidity. The non-forming portion can be dissolved in a cleaning solution to remove.

The cleaning solution is preferably wobbled or moved. When the cleaning solution is wobbled or flowed, dissolution of the non-forming portion can be promoted.

Furthermore, the cleaning step preferably includes a method of ejecting a cleaning solution that dissolves the forming material having the fluidity to a surface of the substrate covered with the forming mold.

The cleaning solution being ejected is preferably in the form of mist. When the cleaning solution is in the form of mist, it can be delivered over the substrate without causing irregularity.

Still furthermore, the cleaning step preferably includes a method of ejecting a gas on a substrate surface covered with the forming mold. With ejection pressure of a gas as well, the non-forming portion can be removed.

In the respective cleaning steps, a cleaning solution remaining on the substrate surface is desirably removed by ejecting a gas. With ejection pressure of a gas, the cleaning solution can be effectively removed.

The forming material having the fluidity can be a sol-gel material. In this case, the cleaning solution is preferably water.

The forming material having the fluidity can be a resin material. In this case, the cleaning solution is preferably an organic solvent that dissolves the resin material.

According to the invention, a producing method where, before a forming material is cured in the forming step, a non-forming portion can be removed, and, without applying a complicated removing step, only a formed portion is remained can be provided.

### BRIEF DESCRIPTION OF THE DRAWINGS

FIGS. 1A through 1E are diagrams for explaining producing steps of an article having an island structure according to the invention.

FIGS. 2A and 2B are schematic diagrams showing an example of an article having an island structure prepared according to a producing method of the invention.

FIG. 3 is a schematic diagram showing another example of an article having an island structure prepared according to a producing method of the invention.

FIGS. 4A and 4B are diagrams showing a configuration example of a plurality of photodiode arrays formed on a substrate.

FIGS. 5A and 5B are schematic diagrams showing an island structure formed on a photodiode array.

FIG. 6 is a schematic diagram of a so-called moth eye structure.

FIG. 7 is a diagram showing one example of a cleaning method of the invention.

FIGS. 8A through 8D are diagrams for explaining producing steps of an existing formed article.

FIGS. 9A through 9D are diagrams for explaining another producing step of an existing formed article.

FIG. 10 is a schematic cross sectional diagram of a formed article prepared according to an existing producing method.

### DETAILED DESCRIPTION OF THE PREFERRED EMBODIMENTS

In what follows, embodiment of the invention will be detailed.

### First Embodiment

In the embodiment, a forming material is a sol-gel material. The sol-gel material is coated on a glass substrate and a forming mold is pressed thereto to prepare a formed body.

As the glass substrate, a 50 mm square quartz glass substrate having a thickness of 3 mm was used. As the sol-gel material, a material ([a material obtained by adding polyethylene glycol to tetraethoxysilane] and [a material obtained by mixing methyltriethoxysilane to tetraethoxysilane]) that forms an organo-polysiloxane film was used.

As a forming mold, a quartz glass forming mold having a plurality of parallel linear groove structures (groove width 1 μm, groove depth 1 μm and magnitude of 20 mm square) was used. The groove has a V-character shape in a cross section perpendicular to a linear direction.

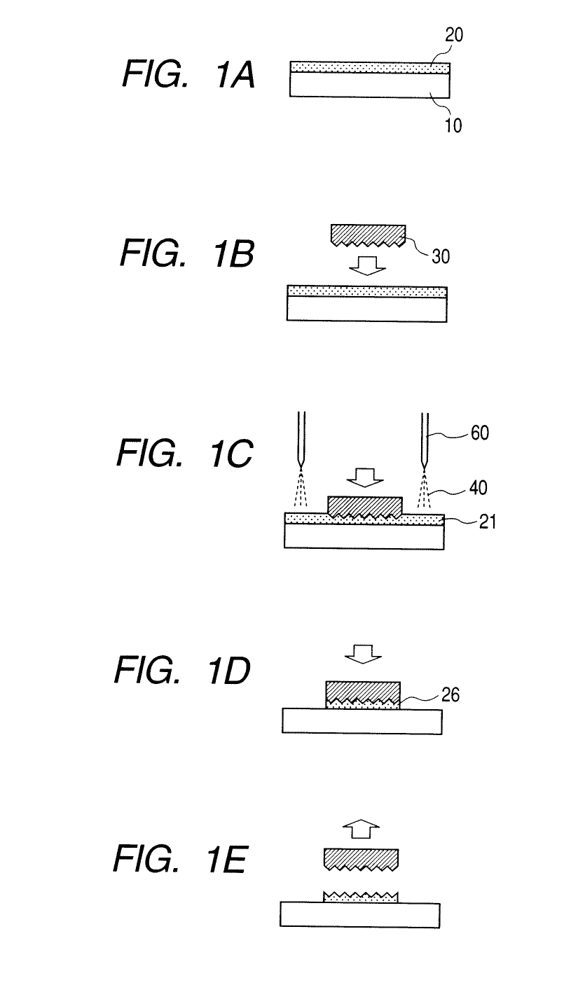

FIGS. 1A through 1E are diagrams showing producing steps of the invention.

In the beginning, a spin coating method was used to coat the sol-gel material as the forming material 30 on the glass substrate 10 substantially uniformly at a thickness of substantially 1 μm (coating step, FIG. 1A). On the glass substrate 10 on which the sol-gel material was uniformly coated, a forming mold 30 is placed and pressurized (forming step, FIG. 1B). The forming steps up to the step are same as that of an existing forming step.

In the next place, in the step according to the invention, in a pressurized state as is, from above the glass substrate 10, pure water that is a cleaning solution 40 is ejected from a nozzle 60 in the form of mist to remove a sol-gel film 21 of a portion where a forming mold is not on the glass substrate 10 (cleaning step, FIG. 1C). After the removal, dry air is sprayed to remove moisture remaining on a surface of the glass substrate.

Thereafter, the glass substrate is held at 70° C. for 1 hr and thereby the sol-gel material is substantially completely dehydrated and polycondensated to gelate (curing step, FIG. 1D). Finally, the forming mold is removed to release (mold releasing step, FIG. 1E).

Owing to the above steps, only a sol-gel material of a formed portion 26 where a surface shape of the forming mold is reversed is remained on a surface of the glass substrate. The glass substrate is further fired at 300° C. for 30 min. By carrying out thus, on the glass substrate, a film of organosiloxane only a formed portion of which is cured (hereinafter referred to as “sol-gel film”) remains.

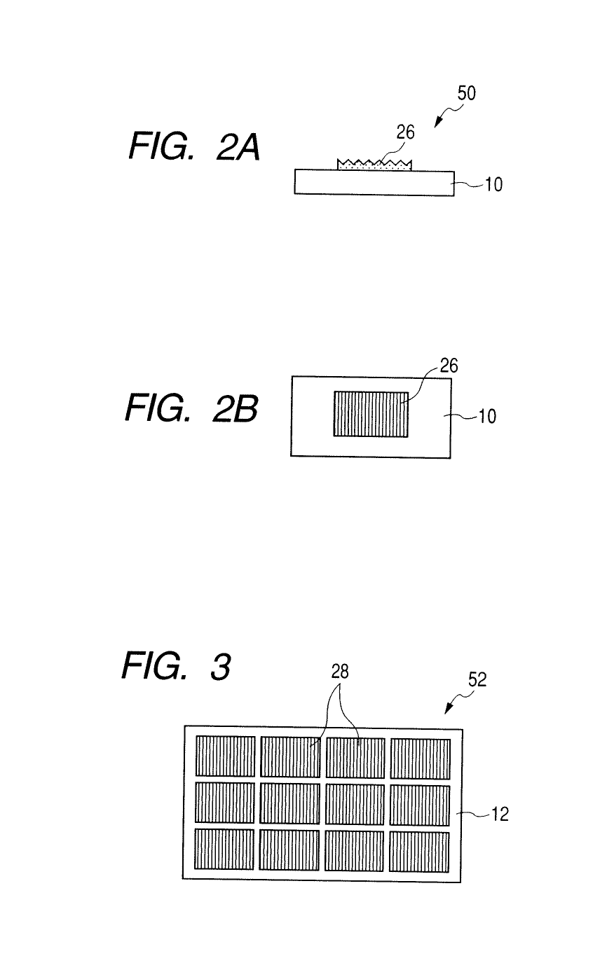

A sol-gel film thus prepared remains, as shown in FIGS. 2A and 2B, with only a formed portion 26 protruded to the glass substrate 10. FIG. 2A is a sectional diagram vertical to a substrate surface and FIG. 2B is a plan view of a formed article 50. The formed article 50 has a shape appropriate to use as a forming mold once more.

Furthermore, when the similar cleaning step is used, as shown in FIG. 3, a formed article 52 in which a plurality of formed portions 28 is formed on the same substrate can be prepared. This can be used as a forming mold for simultaneously forming a plural, in which a plurality of forming molds is arranged on the same substrate. When the formed body is cut for every formed portion 28 at a portion where the substrate is exposed to separate, by one-time forming, many optical elements can be prepared.

Furthermore, in the case of a formed article being applied as an optical element, even when an antireflective film (multi-layered film obtained by layering TiO₂ and SiO₂: total film thickness substantially 2 μm) substantially totally reflective in a wavelength range of 680 to 880 nm is layered on a surface of the formed body by means of the sputtering method, since a film of the non-forming portion assumed to be large in the thermal expansion coefficient is removed, a problem such as peeling can be inhibited from occurring.

### Second Embodiment

The embodiment is a case where a UV-curable epoxy resin is used as a forming material.

In the steps shown in FIGS. 1A through 1E, as a forming material 20, a UV-curable epoxy resin is used, and a forming mold 30 is pressed against this to form a formed article.

As a glass substrate 10, a quartz glass substrate having a dimension similar to a first embodiment was used. As an epoxy resin material, a material that can be cured by UV rays was used. As a forming mold 30 as well, one having same shape as that of the first embodiment was used.

In the beginning, an epoxy resin material having the fluidity was coated on a glass substrate by use of a micropipette. On the glass substrate thereon the epoxy resin material was coated, a forming mold is placed and pressurized. In a pressurized state, from an upper portion of the glass substrate, acetone that is an organic solvent is ejected in the form of mist to dissolve and remove an epoxy resin film of a portion where the forming mold is not present on the glass substrate. After removing, acetone remaining on a surface of the glass substrate was removed by spraying dry air.

In the next place, from a back surface of the glass substrate, UV rays are irradiated to cure the epoxy resin. After that, the forming mold is removed to release and thereby only the epoxy resin on which a surface shape of the mold is transferred is remained on the surface of the glass substrate. The glass substrate is fired at 100° C. for 1 hr. When thus carrying out, on the glass substrate, a formed body where only a formed portion is cured can be formed.

A formed portion of an epoxy film thus prepared as well remains in a protruded state to the glass substrate as shown FIGS. 2A and 2B; accordingly, it has a shape appropriate when the formed body is again used as a forming mold. Furthermore, when a plurality of the formed portions are prepared on a same substrate, as shown in FIG. 3, a mold for simultaneously forming a plural, in which a plurality of forming molds are arranged on a same substrate, can be prepared.

In the embodiment, a case where an epoxy resin material is used as a forming material was described. However, with other resin materials (for instance, acrylic resin), a forming mold having a shape suitable for the press forming can be prepared. In that case, as the cleaning solution, an organic solvent that dissolves the resin material is necessarily used.

### Third Embodiment

The embodiment is a case where a formed body is prepared on a semiconductor substrate on which a light receiving element is formed.

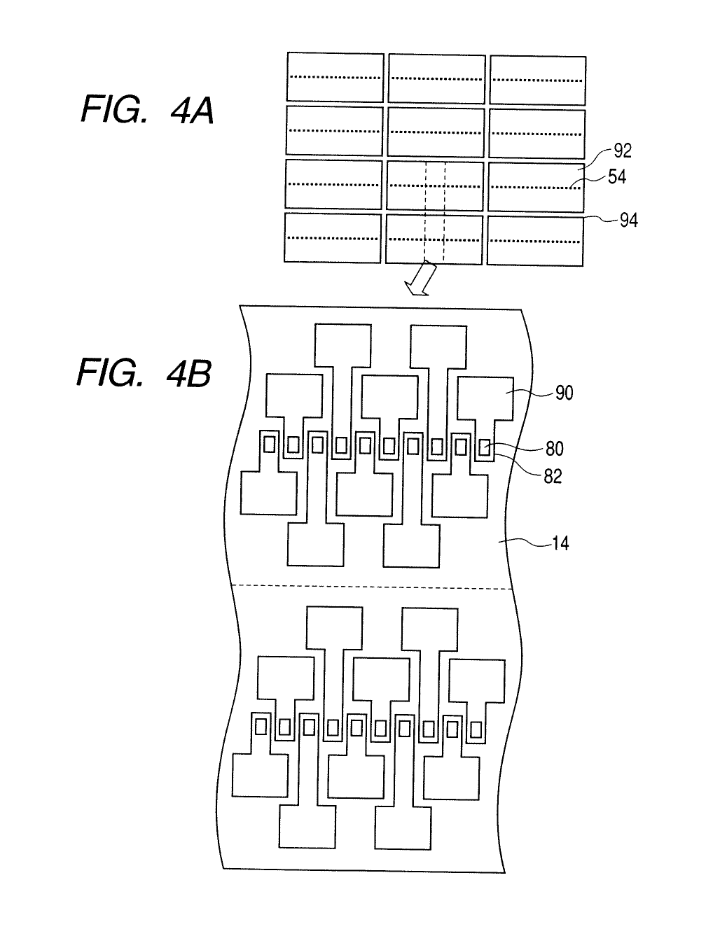

As shown in FIG. 4A, on a semiconductor substrate (omitted from showing in the drawing), a plurality of photodiode elements are arranged in a plurality of linear lines to form a photodiode array 54. When it is industrially produced, it is preferable to form a plurality of array elements on one substrate (semiconductor wafer). FIG. 4A shows a situation of a part on the substrate on which a plurality of array elements are formed. In order to operate a photodiode, an electrical connection is necessary. In order to secure the portion, a region 92 having a definite area is necessary for one array element. Furthermore, since these are finally separated, a cutting margin 94 is necessary between the respective regions.

FIG. 4B is a diagram showing in detail a part of the photodiode array element, which is shown in FIG. 4A surrounded by a chain line. A plurality of photodiode elements 80 are linearly arranged on a substrate 14. Each of the elements is provided with a metal electrode 82 and a bonding pad 90 connecting thereto is formed. To the bonding pad 90, a metal wire (omitted from showing in the drawing) is bonded and thereby an electrical signal generated when a photodiode element 80 receives incident light through the metal wire is externally transmitted.

In the invention, a formed body is prepared by positionally aligning on the photodiode array. As a sol-gel material, a material ([a material obtained by adding polyethylene glycol to tetraethoxysilane] and [a material obtained by mixing methyltriethoxysilane to tetraethoxysilane]) that forms an organo-polysiloxane film was used.

As a forming mold, a quartz glass forming mold having a plurality of conical holes (period 300 nm and hole depth 750 nm) were used.

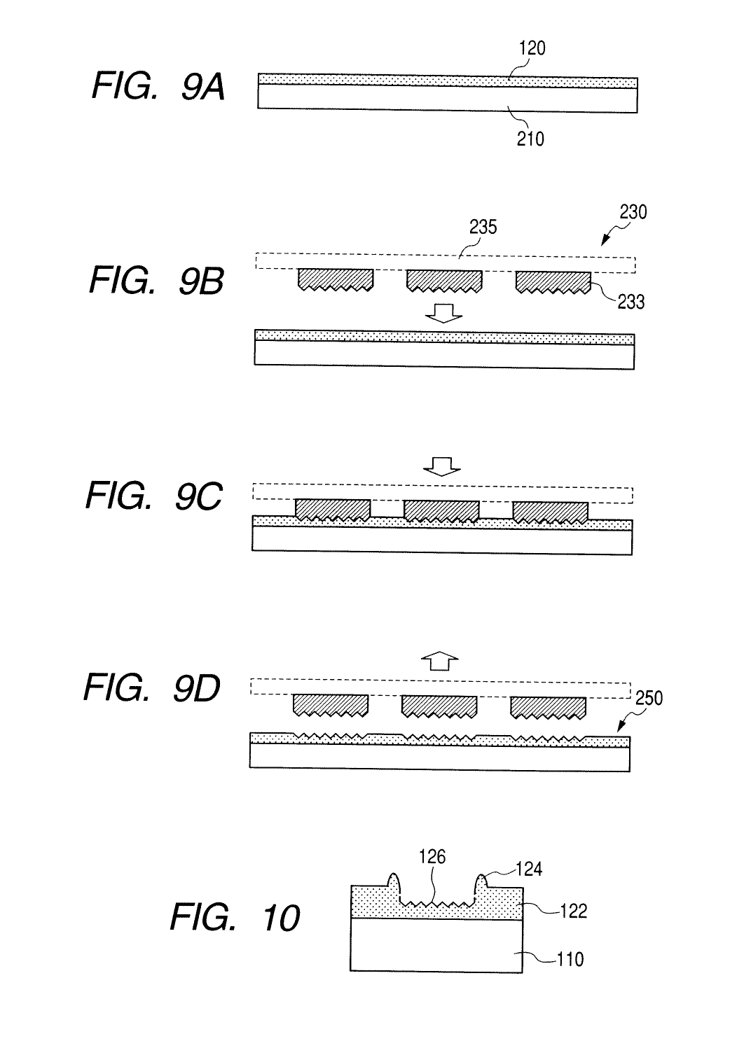

In the beginning, a spin coat method was used to substantially uniformly coat on a substrate a sol-gel material as a forming material at a thickness of substantially 1 μm. On a photodiode element of a substrate on which the sol-gel material was uniformly coated, a forming mold such as shown in FIGS. 9A through 9D is placed positionally aligned followed by applying pressure.

In the next place, in the step according to the invention, under a pressurized state as is, from above the substrate, pure water that is a cleaning solution is ejected in the form of mist from a nozzle to remove a sol-gel film of a portion where the forming mold is not present on the substrate, in particular, a bonding pad portion. After the removal, moisture remaining on a surface of the substrate is removed by spraying dry air.

After that, the substrate is kept at 70° C. for 1 hr, and thereby the sol-gel material is nearly completely dehydrated and polycondensated to gelate. Finally, the forming mold is removed to release.

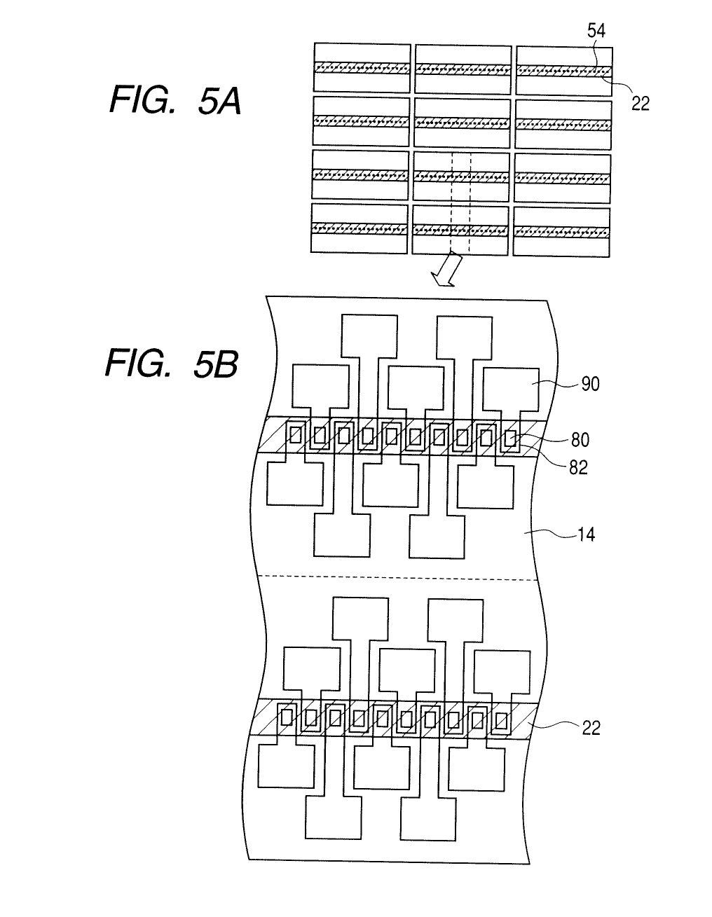

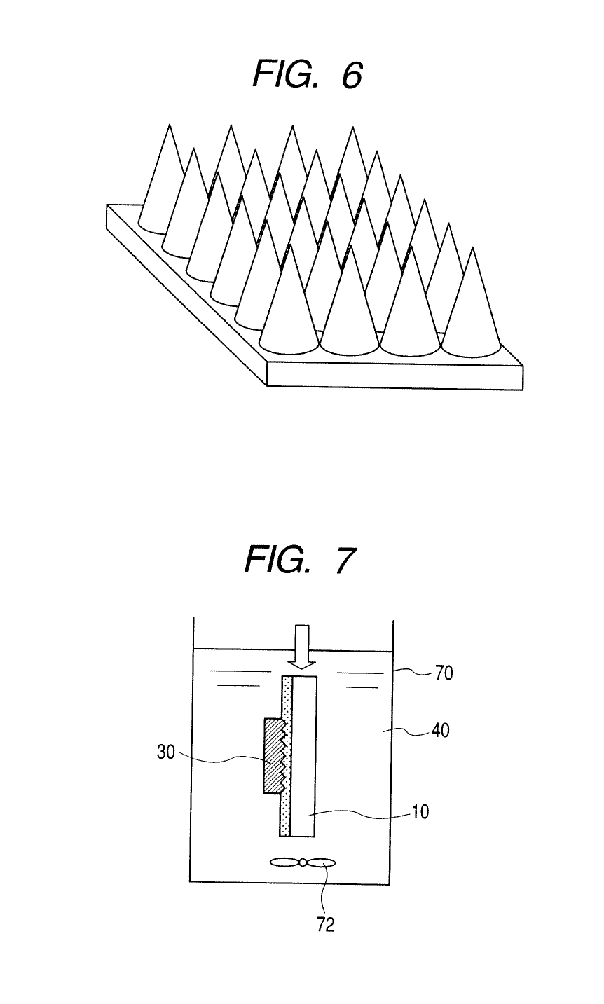

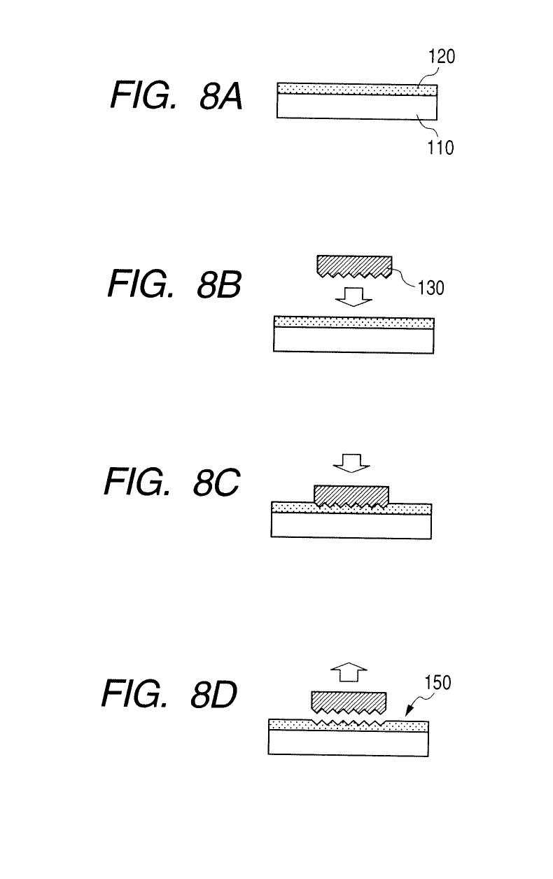

According to the above steps, as shown in FIGS. 5A and 5B, only a sol-gel material 22 of a formed portion where a surface shape of the forming mold is reversed remains on the photodiode array 54. When the substrate is further fired at 300° C. for 30 min, on the photodiode array, fine conical structures made of organo-polysiloxane of which only a formed portion is cured and having a shape such as schematically shown in FIG. 6 are formed. The structure is called a moth eye structure and is known to have anti-reflection effect. Owing to the formation of the structure, light incident on the light receiving element can be reduced from reflecting from a surface of the light receiving element and thereby light receiving efficiency can be improved. Furthermore, since the bonding pad portion is free from the sol-gel material and exposed, after cutting and separation, a metal wire can be immediately bonded.

The embodiment described an example of a photodiode array. However, the invention, without restricting to the light receiving element, can be applied as well to a light-emitting element. To a light-emitting diode array formed on a semiconductor substrate, a formed body similar to the above can be formed. The formed body can be formed into not only an anti-reflective moth eye structure but also into fine lenses or prisms. When a lens is formed on a light-emitting element, since exit light can be condensed, usage efficiency of light can be improved.

(Cleaning Step)

In the cleaning step of the embodiment, a method of ejecting the cleaning solution in the form of mist onto the substrate was adopted. However, the cleaning method is not restricted thereto. The cleaning solution may be sprayed not in the form of mist but in the form of liquid as is. Furthermore, as shown in FIG. 7, in a state where the substrate 10 and the forming mold 30 are pressurized with a forming material interposed therebetween, a whole or a part of the substrate and the forming mold may be dipped in the cleaning solution 40 in a cleaning tank 70. In this case, when the cleaning solution 40 is wobbled with a rotary blade 72 or flowed, the cleaning can be efficiently carried out.

The cleaning solution after the cleaning is desirably removed by ejecting a gas such as dry air or nitrogen as used in the embodiment. However, without applying such methods, it may be heated.

In all of the above methods, a cleaning solution that dissolves a forming material was used. However, a method where air is sprayed as a high-speed airflow to physically remove the forming material may be adopted.

What is claimed is:

1. An article having an island structure comprising:
a plurality of island bodies arranged and formed separately from one another, on a surface of a substrate or a surface of a solid material layer formed on a surface of a substrate,
wherein the island body contains a substance obtained by hydrolyzing and curing a sol-gel material, and, the surface of the substrate or the surface of the solid material layer is exposed in a surrounding portion of each island body.

2. The article having an island structure according to claim 1, wherein the substrate is glass or semiconductor.

3. The article having an island structure according to claim 1, wherein the solid material layer is a semiconductor layer.

4. The article having an island structure according to claim 1, wherein the surface of the substrate and the surface of the solid material layer or either one of the surface of the substrate and the surface of the solid material layer is at least partially provided with an electrically conductive layer.

5. The article having an island structure according to claim 4, wherein a plurality of light-emitting elements and light receiving elements or either of a plurality of light-emitting elements and light receiving elements are formed on the semiconductor layer, the electrically conductive film is provided to form an electrode on a surface of the semiconductor layer, and the island structure is at least partially formed on the light-emitting element and the light receiving element or on either of the light-emitting element and the light receiving element.

6. The article having an island structure according to claim 1, wherein all island bodies on the substrate have a substantially same shape.

7. The article having an island structure according to claim 1, wherein a predetermined irregular structure is formed on a surface of the island body.

8. The article having an island structure according to claim 1, wherein the island bodies are linearly or two-dimensionally arranged according to a predetermined rule.

9. A producing method of an article having an island structure where an island body is partially formed on a surface of a substrate comprising:
a step of coating a forming material having a fluidity on a substrate or filling and coating the forming material in a forming mold;
a step of facing the substrate and a forming mold with the forming material having the fluidity sandwiched therebetween and pressurizing to form;
a step of removing the forming material having the fluidity outside of the forming mold to clean;
a step of applying energy such as heat or light under a pressurized state to cure the forming material in the forming mold; and
a step of releasing the forming mold.

10. The producing method of an article having an island structure according to claim 9, wherein the cleaning step includes a method where in a cleaning solution that dissolves the forming material having the fluidity the substrate covered by the forming mold is partially or wholly dipped.

11. The producing method of an article having an island structure according to claim 10, wherein the cleaning solution is wobbled or flowed.

12. The producing method of an article having an island structure according to claim 9, wherein the cleaning step includes a method where a cleaning solution that dissolves the forming material having the fluidity is sprayed to a surface of a substrate covered with the forming mold.

13. The producing method of an article having an island structure according to claim 9, wherein the cleaning solution ejected is in a form of mist.

14. The producing method of an article having an island structure according to claim 9, wherein the cleaning step includes a method of spraying a gas in the form of mist on a surface of a substrate covered with the forming mold.

15. A producing method of an article having an island structure, wherein, in the cleaning step according to claim 10, a cleaning solution remaining on a surface of the substrate is removed by spraying a gas.

16. The producing method of an article having an island structure according to claim 9, wherein the forming material having the fluidity is a sol-gel material.

17. The producing method of an article having an island structure according to claim 16, wherein the cleaning solution is water.

18. The producing method of an article having an island structure according to claim 9, wherein the forming material having the fluidity is a resin material.

19. The producing method of an article having an island structure according to claim 18, wherein the cleaning solution is an organic solvent that dissolves the resin material.
